(19) United States
(12) Patent Application Publication
(10) Pub. No.: US 2007/0246830 A1
(43) Pub. Date: Oct. 25, 2007

(54) Long-lifetime interconnect structure and method for making

(75) Inventor: Yoshiaki Shimooka, Kanagawa-pref (JP)

Correspondence Address: BANNER & WITCOFF, LTD., 1100 13th STREET, N.W., SUITE 1200, WASHINGTON, DC, 20005-4051, US

(73) Assignee: Toshiba America Electronic Components, Inc., Irvine, CA (US)

(21) Appl. No.: 11/408,183

(22) Filed: Apr. 21, 2006

(51) Int. Cl. H01L 23/52

(52) U.S. Cl. 257/758; 257/E23.168

(57) ABSTRACT

An interconnect structure and method for manufacturing are described wherein an insulating material adjacent to or at least partially surrounding a conductive interconnect has a coefficient of thermal expansion (CTE) equal to or larger than the CTE of the interconnect. For example, a copper-based damascene interconnect layer may be provided, wherein an inter-layer dielectric (ILD) a least partially surrounds the interconnect layer and a cap insulator is disposed on the interconnect layer. In such an embodiment, the CTE of the ILD and/or the cap insulator would be at least as large as the CTE of the interconnect layer. This may result in no stress or compressive stress being applied by the insulating material to the interconnect layer when the device has cooled, such as to room temperature, after formation of the various layers.

### BACKGROUND

There has been a growing problem with interconnect reliability in semiconductor devices. The main reason for this is that the devices are manufactured such that the insulating layers surrounding interconnects typically apply tensile stress to the interconnects. Such tensile stress weakens the interconnect layer and can even extract metal atoms out of the interconnects. This results in a greater risk for a substantial defect in the interconnect structure such that a necessary interconnection is not made or the interconnection has a higher resistance than desired. These problems have become even worse over time as interconnects become thinner and more delicate, and thus more vulnerable to potential defects. It is becoming more likely that interconnects will either not operate properly at all or will prematurely fail at a later point during the device lifetime.

### SUMMARY

There is therefore a need for a more reliable interconnect structure in a semiconductor device, as well as a method for manufacturing such a structure or device. The interconnect structure may include a conductive interconnect layer adjacent to (e.g., partially or fully surrounded by) insulating material, wherein the insulating material has a coefficient of thermal expansion (CTE) that is equal to or larger than the CTE of the interconnect layer. The CTE of a material is the ratio of (a) the change in length of a line segment in the material per unit of temperature change to (b) its length at a reference temperature. In one example, a copper-based damascene interconnect layer may be provided, wherein an inter-layer dielectric (ILD) a least partially surrounds the interconnect layer and a cap insulator is disposed on the interconnect layer. In such an embodiment, the CTE of the ILD and/or the cap insulator would be at least as large as the CTE of the interconnect layer. This may desirably result in no stress or compressive stress being applied by the insulating material to the interconnect layer when the device has cooled, such as to room temperature, after formation of the various layers.

Normally, the CTE of a metal interconnect is larger than that of the insulators used in large-scale integrated circuits (LSIs). When such a structure cools during the manufacturing process, the metal interconnect shrinks more quickly than the surrounding insulating material, resulting in the final product producing tensile stress on the metal interconnect at room temperature. However, when the CTE of the insulating material is made to be at least as large as that of the interconnect material, then the reliability of the interconnect may be significantly improved due to the lack of tensile stress on the interconnect, or at least due to significantly reduced tensile stress as compared with previous devices.

These and other aspects of the invention will be apparent upon consideration of the following detailed description of illustrative embodiments.

### BRIEF DESCRIPTION OF THE DRAWINGS

A more complete understanding of the present invention and the advantages thereof may be acquired by referring to the following description in consideration of the accompanying drawings, in which like reference numbers indicate like features, and wherein:

FIGS. 1 and 3 are graphs showing illustrative relationships between temperature and changes in material line lengths.

FIGS. 2 and 4 are side cut-away views illustrating how different CTE ratios can affect whether tensile or compressive stress are applied to an interconnect layer.

FIGS. 5-8 are side cut-away views of an interconnect structure at various steps in an illustrative manufacturing process.

FIGS. 9 and 10 are side cut-away views of another interconnect structure at two steps in another illustrative manufacturing process.

FIG. 11 is a side cut-away view of an illustrative semiconductor device incorporating the interconnect structure of FIG. 8.

### DETAILED DESCRIPTION OF ILLUSTRATIVE EMBODIMENTS

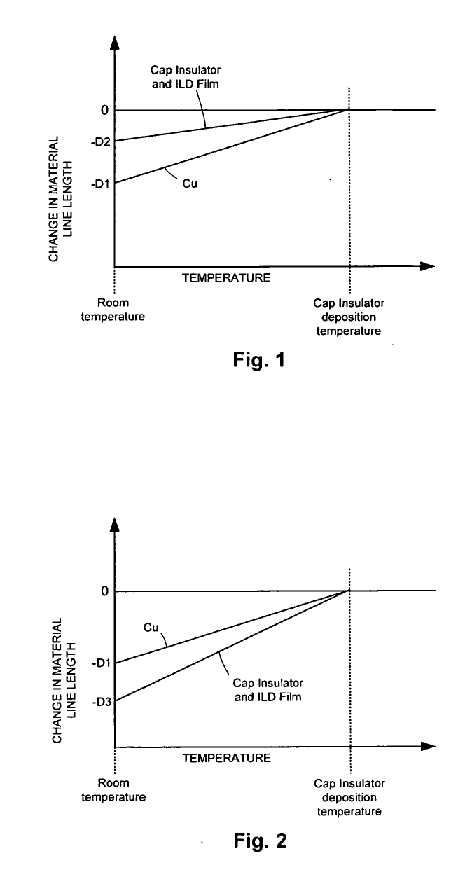

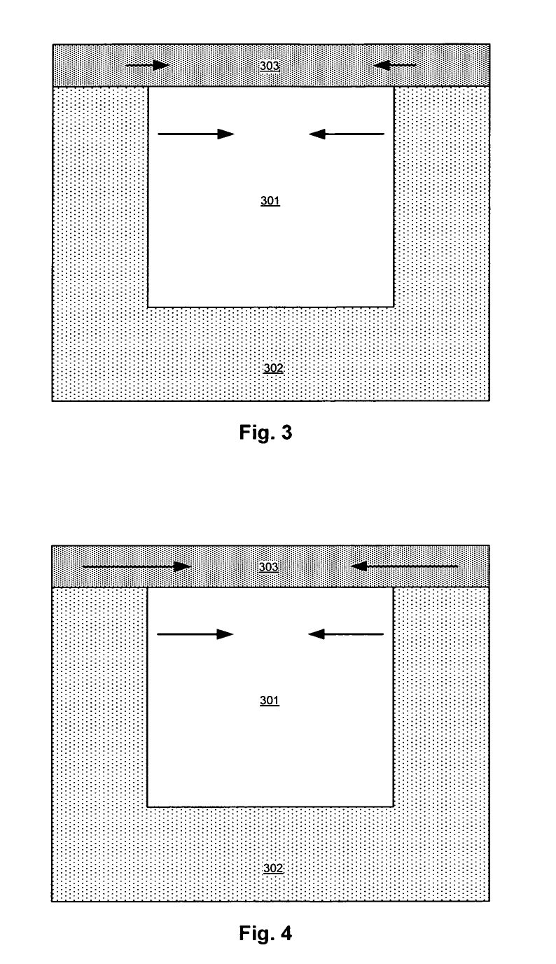

FIGS. 1 and 3 show an example of what happens when a cap insulator film 303 has a coefficient of thermal expansion (CTE) that is smaller than the CTE of a copper interconnect layer 301. Copper interconnect layer 301 is disposed in a trench in an interlayer dielectric (ILD layer 302. Then, cap insulator film 303 is deposited over interconnect layer 301 while at a deposition temperature higher than room temperature. The deposition temperature may be, for example, between 300 and 400 degrees C., whereas room temperature may be, for example, between 20 and 25 degrees C. Such cooling may occur over a temperature differential of at least 100 degrees C., such as in the rage of about 200 to 400 degrees C. As seen in FIG. 1, there is a smaller amount of line length change (shrinkage) in cap insulator film 303 as compared with copper interconnect layer 301, as the device cools. In particular, copper interconnect layer 301 shrinks by a distance −D1 while cap insulator film 303 shrinks by a distance −D2, wherein the magnitude of D2 is smaller than the magnitude of D1.

FIG. 3 depicts this line length shrinkage with arrows, where a longer arrow represents more shrinkage than a shorter arrow. The result is that, while there is no stress at the interface between interconnect layer 301 and cap insulator film 303 at deposition temperature, a stress develops at that surface upon cooling that tends to pull interconnect layer 301 away from itself. In other words, cap insulator film 303 applies tensile stress to interconnect layer 301 upon device cooling, such as at room temperature. Such stresses may also occur at the interface between ILD layer 302 and interconnect layer 301.

In contrast, FIGS. 2 and 4 show an example of what happens when cap insulator film 303 has a CTE that is larger than the CTE of copper interconnect layer 301. As seen in FIG. 2, there is a larger amount of line length change (shrinkage) in cap insulator film 303 as compared with copper interconnect layer 301, as the device cools. In this case, copper interconnect layer 301 shrinks by distance −D1 while cap insulator film 303 shrinks by a distance −D3, wherein the magnitude of D3 is greater than the magnitude of D1.

FIG. 4 depicts this line length shrinkage with arrows, where a longer arrow represents more shrinkage than a shorter arrow. The result is that, while there is no stress at the interface between interconnect layer 301 and cap insulator film 303 at deposition temperature, a stress develops at that surface upon cooling that tends to compress interconnect layer 301 into itself. In other words, cap insulator film 303 applies compressive stress to interconnect layer 301 upon device cooling, such as at room temperature.

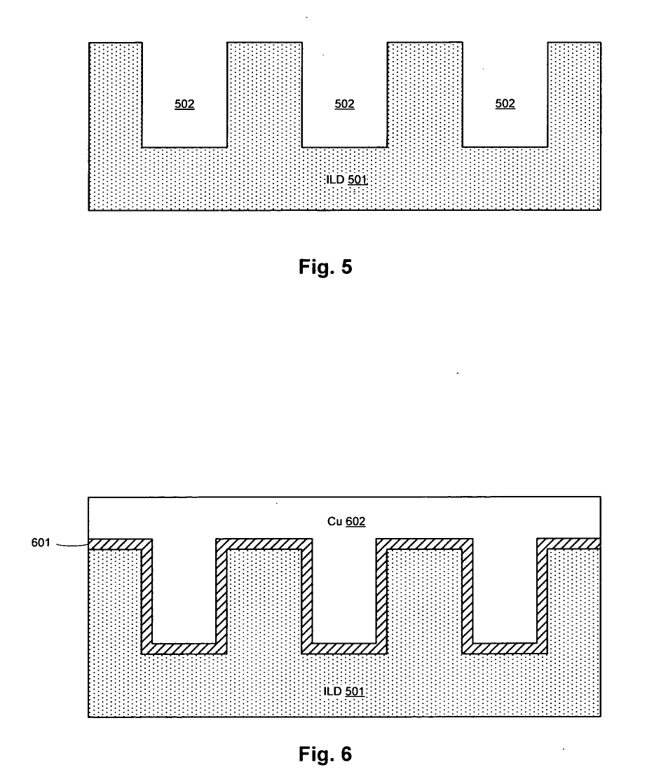

An illustrative method for manufacturing a damascene interconnect structure and a device having the interconnect structure will now be discussed with reference to FIGS. 5-8. Referring to FIG. 5, an inter-layer dielectric (ILD) layer 501 is formed over other layers of the device (not shown). ILD layer 501 may have a thickness of, for example, in the range of about 200 nm to 5 μm. Then, a plurality of trenches 502 are formed in ILD layer 501. Trenches may have a depth of, for example, in the range of about 50 nm to 2 μm. Trenches 502 may be elongated and parallel to each other over at least a portion of their lengths.

Referring to FIG. 6, a barrier layer 601, which may be, for example, TiN, TaN, Ti, Ta, or SiN, is deposited over the surface of ILD layer 501 including the surfaces of trenches 502. Next, a conductive layer 602, such as copper or other metal, is formed over barrier layer 601. Conductive layer 602 may be made of any single conductive material or combination of conductive materials, such as metal. For example, conductive layer 602 may be copper, aluminum, or tungsten. Barrier layer 601 may help reduce or prevent migration of material from conductive layer 602 into surrounding ILD layer 501.

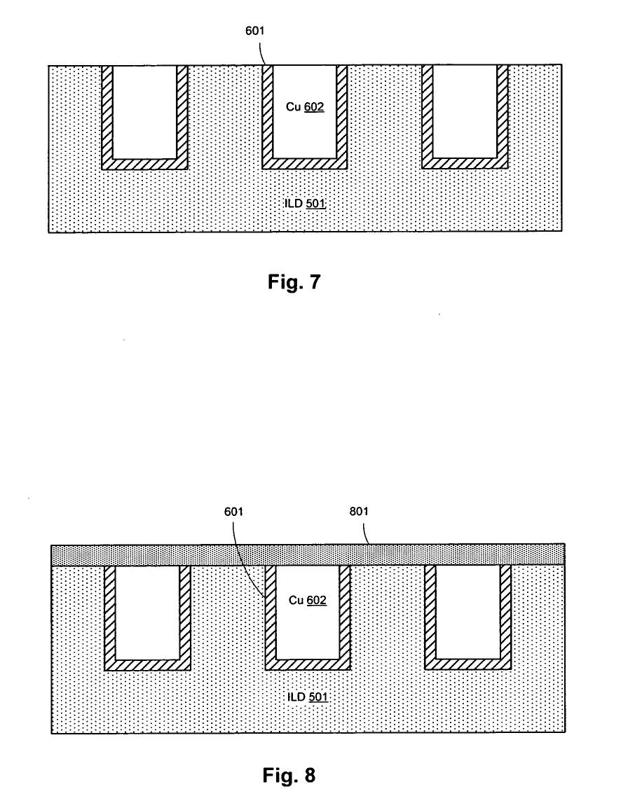

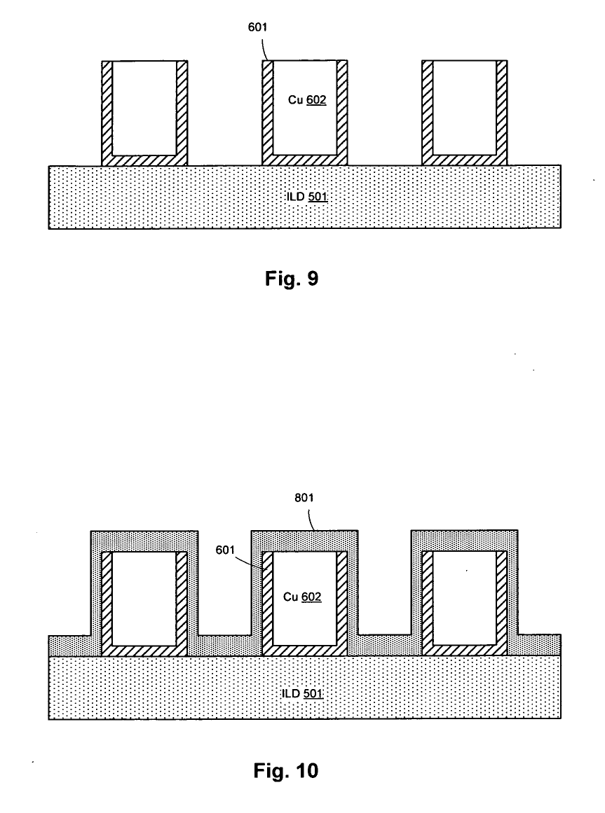

Next, referring to FIG. 7, a portion of conductive layer 602 and barrier layer 601 is removed, such as by chemical mechanical polishing (CMP). This results in conductive layer 602 forming a series of separate parallel conductive paths. Referring to FIG. 8, a cap insulator film 801 is then deposited over the exposed surface. Cap insulator film 801 may have a thickness of, for example, in the range of about 30 nm to 100 nm. As previously discussed, ILD layer 501 and/or cap insulator film 801 each have a CTE that is greater than or equal to the CTE of conductive layer 602.

An alternative example of a method for manufacturing the device is discussed with reference to FIGS. 9 and 10. The manufacturing begins as in FIGS. 5-7. However, after the structure of FIG. 7 is produced, the steps of FIGS. 9 and 10 are performed. Referring to FIG. 9, ILD layer 501 is recessed, such as by a reactive ion etching (RIE) process. Then, in FIG. 10, cap insulator film 801 is formed over the exposed surface. Also in this embodiment, ILD layer 501 and/or cap insulator film 801 each have a CTE that is greater than or equal to the CTE of conductive layer 602.

Different materials may have different CTEs. Although the CTE of a given material may depend upon a variety of factors, several examples of CTEs are as follows: the CTE of copper (Cu) is about 16×10⁻⁶/K, the CTE of silicon nitride (SiN) is about 2.2×10⁻⁶/K, the CTE of silicon carbide (SiC) is about 4.2×10⁻⁶/K, the CTE of TEOS is about 0.3×10⁻⁶/K, and the CTE of a standard silicon-based chemical vapor deposition (CVD) film is about 12×10⁻⁶/K.

Two specific examples of the manufacturing of high-CTE insulating materials will now be discussed. Variations of these recipes may also result in appropriate materials. Each of the following recipes is estimated to produce an insulating material having a CTE at least as large as the CTE of copper.

In one example, cap insulator film 801 may be manufactured from a high-CTE silicon carbonitride (SiCN). To make such a material, the following recipe may be used:
precursor gas: tri-methyl silicane (3MS) less than 160 standard cubic centimeters per minute (sccm) flow rate;
RF power greater than 300 watts;
helium (He) gas greater than 280 sccm flow rate;
(NH3) gas less than 325 sccm flow rate;
pressure greater than 3 Torr; and
temperature at about 350 degrees C.

In another example, ILD layer 501 may be manufactured from a high-CTE hydrogenated silicon oxycarbide (SiCOH). To make such a material, the following recipe may be used:
oxygen (O2) gas greater than 450 sccm flow rate;
RF power less than 700 watts;
pressure greater than 4.5 Torr;
precursor gas: 3MS, tetra-methyl-cyclic-tetra-silane (TMCTS), or octa-methyl-cyclic-tetra-silane (OMCTS), greater than 1100 sccm flow rate;
helium (He) gas greater than 200 sccm flow rate;
temperature at about 350 degrees C.

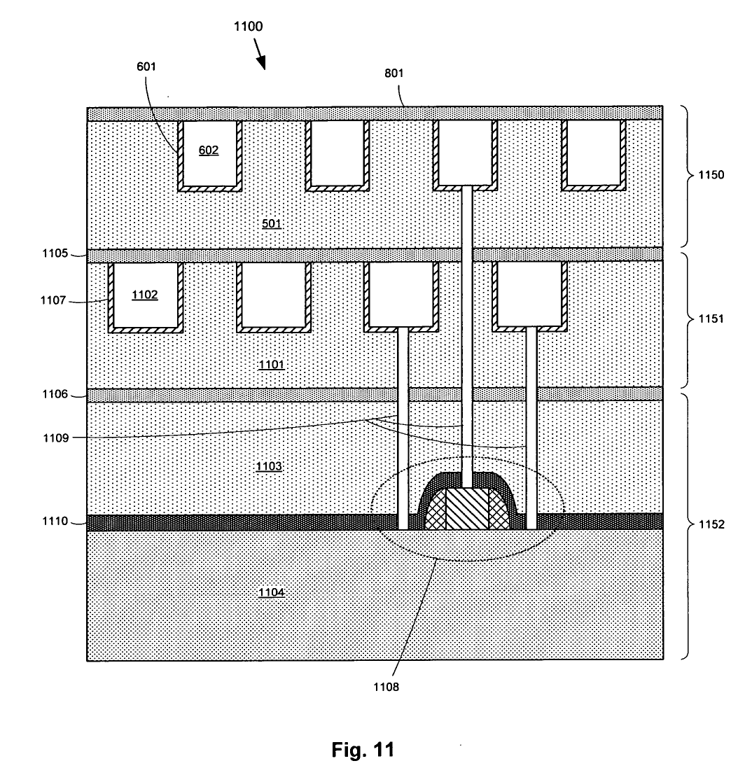

Referring to FIG. 11, the interconnect structure described in FIG. 8 is shown as level 1150 incorporated into a larger illustrative semiconductor device 1100. Device 1100 as shown includes level 1150 disposed on top of a lower similar structure, referred to as level 1151, having another interconnect layer 1102 and ILD layer 1101, separated by a barrier layer 1107. Level 1151 is separated from level 1150 by a cap insulating layer 1105, and is further separated from a lower component level 1152 having an ILD layer 1103, a silicon layer 1104, and a lower cap layer 1110 such as silicon nitride.

Components, such as transistor 1108, may be disposed in ILD layer 1103 and/or silicon layer 1104, such as between lower cap layer 1110 and silicon layer 1104. Silicon layer 1104 may be the main substrate of semiconductor device 1100 or it may be disposed on one or more further layers below, such as on an insulating layer (not shown). Components in component layer 1152 may have vertical connection paths 1109 (such as tungsten or another metal or other conductive material) electrically connecting the components to various ones of the conductive horizontal lines of interconnect layers 602 and/or 1102. Connection paths 1109 may be perpendicular to the lengthwise direction of interconnect layers 602 and/or 1102. The present device is merely illustrative, and modifications may be made. For example, additional interconnect and/or component levels may be included, and the interconnect layers may be electrically interconnected between levels.

Thus, a device and its method for manufacturing have been discussed in which the CTE of a conductive interconnect is lower than the CTE of insulating material adjacent to or even partially surrounding the interconnect. The result is that the conductive interconnect may be under reduced neutral or compressive stress at operating/room temperatures, thus increasing the reliability of such an interconnect.

What is claimed is:

1. A semiconductor device, comprising:
a silicon layer;
a first insulating layer disposed on the silicon layer and having a plurality of trenches;
a conductive interconnect layer disposed in the plurality of trenches; and
a second insulating layer disposed on both the interconnect layer and the first insulating layer,
wherein a coefficient of thermal expansion of at least one of the first and second insulating layers is at least as large as a coefficient of thermal expansion of the interconnect layer.

2. The semiconductor device of claim 1, wherein the coefficient of thermal expansions of both the first and second insulating layers are each at least as large as the coefficient of thermal expansion of the interconnect layer.

3. The semiconductor device of claim 1, wherein the interconnect layer is comprised of metal.

4. The semiconductor device of claim 1, wherein the interconnect layer is comprised of copper.

5. The semiconductor device of claim 1, further including a layer disposed in the plurality of trenches and separating the interconnect layer from the first insulating layer.

6. The semiconductor device of claim 1, wherein the plurality of trenches are parallel to each other.

7. The semiconductor device of claim 1, further including a material separating the first insulating layer from the silicon layer.

8. A semiconductor device, comprising:
a silicon layer;
a first insulating layer disposed on the silicon layer;
a conductive layer disposed on the first insulating layer; and
a second insulating layer disposed on both the conductive layer and the first insulating layer,
wherein a coefficient of thermal expansion of at least one of the first and second insulating layers is at least as large as a coefficient of thermal expansion of the conductive layer.

9. The semiconductor device of claim 8, wherein the conductive layer is a damascene conductive layer.

10. The semiconductor device of claim 8, wherein the coefficient of thermal expansions of both the first and second insulating layers are each at least as large as the coefficient of thermal expansion of the conductive layer.

11. The semiconductor device of claim 8, wherein the conductive layer is comprised of metal.

12. The semiconductor device of claim 8, wherein the conductive layer is comprised of copper.

13. The semiconductor device of claim 8, wherein the conductive layer includes a plurality of parallel conductive paths.

14. The semiconductor device of claim 8, further including a material separating the first insulating layer from the silicon layer.

15. A method for manufacturing a semiconductor device, comprising:
providing a silicon layer;
forming a first insulating layer on the silicon layer;
forming a plurality trenches in the first insulating layer;
forming a conductive layer over the insulating layer including in the plurality of trenches;
removing a portion of the conductive layer to form a plurality of separate conductive paths; and
forming a second insulating layer on the conductive layer,
wherein a coefficient of thermal expansion of at least one of the first and second insulating layers is at least as large as a coefficient of thermal expansion of the conductive layer.

16. The method of claim 15, further including forming a barrier layer on the first insulating layer, wherein the step of removing further includes removing a portion of the barrier layer.

17. The method of claim 15, wherein the coefficient of thermal expansions of both the first and second insulating layers are each at least as large as the coefficient of thermal expansion of the conductive layer.

18. The method of claim 15, wherein the conductive layer is comprised of copper.

19. The method of claim 15, further including removing a portion of the first insulating layer after the step of forming the plurality of trenches.

20. The method of claim 15, further including forming a material on the silicon layer before the step of forming the first insulating layer.
